(19) United States
(12) Patent Application Publication
(10) Pub. No.: US 2022/0255097 A1
(43) Pub. Date: Aug. 11, 2022

(54) SELF-POWERED SYSTEM AND METHOD FOR POWER EXTRACTION AND MEASUREMENT OF ENERGY-GENERATOR UNITS

(71) Applicant: Universitat De Barcelona, Barcelona (ES)

(72) Inventors: Albert Alvarez Carulla, Barcelona (ES); Pedro Luis Miribel Catala, Barcelona (ES); Yaiza Montes Cebrian, Barcelona (ES); Jordi Colomer Farrarons, Barcelona (ES)

(73) Assignee: Universitat De Barcelona, Barcelona (ES)

(21) Appl. No.: 17/626,899

(22) PCT Filed: Jul. 16, 2020
(86) PCT No.: PCT/EP2020/070108

§ 371 Date: Jan. 13, 2022

(30) Foreign Application Priority Data
Jul. 17, 2019 (EP) 19382604.7

(51) Int. Cl. H01M 8/04537; G01R 21/06; G01R 31/385

(52) U.S. Cl. CPC H01M 8/04582; G01R 31/385; G01R 21/06

(57) ABSTRACT

A self-powered system and a method for power extraction and measurement of energy-generator units are disclosed. The system comprises an energy generator unit (10) providing an electrical current I_{FC} and a voltage V_{FC}; an instrumentation block (20) to measure the electrical current I_{FC}; and a power management unit (30) connected to the energy generator unit (10) via a first input that collects the electrical current I_{FC}, extracting an electrical power provided by the energy generator unit (10). The power management unit (30) also has a second input which is connected to a feedback element (40) connected to a voltage reference V_{REF}, to the voltage V_{FC} and to the instrumentation block (20). A variation of an equivalent input impedance of the power management unit (30) sets a given parameter of the energy generator unit (10) to a controlled given value and the instrumentation block (20) assists in the control of the parameter.

### TECHNICAL FIELD

The present invention relates to the field of power supply systems. In particular, the invention relates to a self-powered system and to a method for power extraction and measurement of energy-generator units such as galvanic cells, fuel cells and electric batteries.

### BACKGROUND ART

A particular type of energy-generator units are fuel cells. Until recently, fuel cells have been used as a power source or as an amperometric sensor, but not as both simultaneously (i.e. its functionalities are time-multiplexed) [1-7].

When a fuel cell is used as a power source, power extracted depends on fuel concentration and polarization voltage of the cell among other variables, like electrode variables (area, material, geometry, etc.), external variables like temperature, and solution variables of the sample or fuel. The fuel concentration is the variable to be measured and cannot be controlled or modified. Instead, for a given fuel concentration, a maximum power peak is present for a common-to-all concentrations polarization voltage. This polarization voltage, or V_{P}_{_{MAX}}, is an intrinsic characteristic of the fuel cell. Thus, to extract maximum power from a fuel cell and operate with maximum efficiency, from fuel cell point of view, the strategy is to set the polarization voltage to V_{P}_{_{MAX}}. Power can vary from pW to kW. In terms of enzymatic fuel cells, power density varies from few μWcm⁻² to few mWcm⁻², with an Open-Circuit Voltage (OCV), which is the voltage generated by the cell with no load charge applied between their output terminals, of few mv.

In contrast, when a fuel cell is used as an amperometric sensor, the fuel cell is polarized at a polarization voltage, or V_{SENSOR}, while current outputted by the fuel cell is measured as an indicator of the fuel concentration. In this case, the polarization voltage level to be used depends on multiple variables like sensitivity, linearity or signal-to-noise ratio, among others.

Apart from that, fuel cell-based self-powered state-of-the-art devices usually consist of a Power System, like a Power Management Unit (PMU), and an instrumentation electronics, like a front-end. The PMU is the first module to be powered and the responsible to extract and manage the power generated by the fuel cell. Usually, voltage levels provided by a single-stack fuel cell are low and need to be boosted to higher values in order to be able to power the electronic modules of the device. Two approaches are used to perform the boosting: 1) to implement a Multi-stack Fuel Cell (MFC) with its stacks in series or 2) to use a DC/DC converter to boost the voltage level electrically. The first approach has three major drawbacks: the need for a larger volume of the sample, the devirtualization of its polarization curve, i.e., its transfer function, and a higher cost. On the other hand, the second approach does not need to increase the volume of the sample, it allows to implement a power management like Maximum Power Point Tracking (MPPT) algorithms and, because it uses a well-established silicon-based manufacturing technology, the cost is lower than in the first approach. Finally, the energy extracted by the PMU from the fuel cell is usually stored in a storage element like a supercapacitor, or C_{DD}. Once enough energy is stored in the storage element to power the front-end, PMU is disconnected from the fuel cell allowing to the front-end to perform the corresponding amperometric measurement.

The front-end module, responsible to perform the amperometric measurement, usually consists in a potentiostat architecture. The potentiostat sets the polarization voltage of the fuel cell to V_{SENSOR} and then measures the current outputted by the fuel cell providing an output voltage signal, or V_{SENSE}, as an indicator of the sample concentration. The submodule that sets the polarization voltage consists of a Control Amplifier (CA) that controls the potential differential between the Reference (RE) and Working (WE) Electrodes of a three-terminal electrochemical cell. In specific cases of fuel cells, the electrochemical cell only has two terminals, being RE and the Counter Electrode (CE) short-circuited. By contrast, different approaches are used to implement the current measurement submodule [8-10]. Two of most used approaches are shown in FIG. 1A and FIG. 1B. The first one uses a Transimpedance Amplifier (TIA) basing its operation in the virtual ground established in WE, and the second one uses an Instrumentation Amplifier (IA) that uses a shunt resistor to measure the current provided by the fuel cell.

The known approaches use a fuel cell with its power source and sensor functionalities time-multiplexed and, usually, without concerning in how power is extracted in terms of efficiency. This is the case for example of the current known Point-of-Care devices for Testing (POCT) where tracking and amperometric measurement cannot take place at once, in a controlled way.

More solutions are therefore needed for energy-generator units, such as fuel cells, among others, for example to be used for POCT, in order to be able to extract energy efficiently from the energy-generator unit while a parameter thereof (for example, the polarization voltage, among others) is measured simultaneously.

The above explanations can be extended to other energy-generator units, in particular to an electric battery where the electrolyte concentration of the battery plays a significant role along the battery life.

### REFERENCES OF BACKGROUND ART

[1] M. Grattieri and S. D. Minteer, “Self-Powered Biosensors,” ACS Sensors. 2018.
[2] A. Baingane y G. Slaughter, «Self-Powered Electrochemical Lactate Biosensing», Energies, vol. 10, no. 10, p. 1582, oct. 2017.
[3] A. N. Sekretaryova, V. Beni, M. Eriksson, A. A. Karyakin, A. P. F. Turner, y M. Y. Vagin, «Cholesterol self-powered biosensor», Anal. Chem., vol. 86, no. 19, pp. 9540-9547, 2014.
[4] A. Ruff, P. Pinyou, M. Nolten, F. Conzuelo, y W. Schuhmann, «A Self-Powered Ethanol Biosensor», ChemElectroChem, vol. 4, no. 4, pp. 890-897, abr. 2017.
[5] G. Slaughter y T. Kulkarni, «Highly Selective and Sensitive Self-Powered Glucose Sensor Based on Capacitor Circuit», Sci. Rep., vol. 7, no. 1, p. 1471, dic. 2017.
[6] M. Aller Pellitero, A. Guimerà, R. Villa, y F. J. del Campo, «iR Drop Effects in Self-Powered and Electrochromic Biosensors», J. Phys. Chem. C, vol. 122, no. 5, pp. 2596-2607, feb. 2018
[7] M. A. Pellitero et al., «Quantitative self-powered electrochromic biosensors», Chem. Sci., vol. 8, no. 3, pp. 1995-2002, feb. 2017
[8] J. Punter, J. Colomer-Farrarons, and P. LI., “Bioelectronics for Amperometric Biosensors,” in State of the Art in Biosensors—General Aspects. InTech, March 2013.
[9] Y. Montes-Cebrián et al., “A Fuel Cell-based adaptable Self-Powered Event Detection platform enhanced for biosampling applications—IEEE Conference Publication,” in 2018 Conference on Design of Circuits and Integrated Systems (DCIS), DOI 10.1109/DCIS.2018.8681482. Lyon: IEEE, 2018.
[10] Y. Montes-Cebrián et al., “‘Plug-and-Power’ Point-of-Care diagnostics: A novel approach for self-powered electronic reader-based portable analytical devices,” Biosensors and Bioelectronics, vol. 118, DOI 10.1016/j.bios.2018.07.034, pp. 88-96, 2018.

### SUMMARY OF INVENTION

Aspects of the invention are defined in the attached independent claims with preferable embodiments being defined in the dependent claims.

Disclosed herein is a self-powered system that, as known in the field, comprises an energy generator unit to provide an electrical current I_{FC} and a voltage V_{FC}; an instrumentation block electrically connected to the energy generator unit to measure the electrical current I_{FC} provided by the energy generator unit; and a power management unit electrically connected to the energy generator unit via a first input that collects the electrical current I_{FC}, extracting, as a result, an electrical power provided by the energy generator unit.

According to the proposed self-powered system, the power management unit further has a second input, which is electrically connected to a feedback element such as a feedback amplifier. The feedback element is electrically connected to a voltage reference V_{REF}, to the voltage V_{FC} provided by the energy generator unit and to an input of the instrumentation block. In this manner, simultaneously to the extraction of the electrical power by the power management unit, the self-powered system can set a given parameter of the energy generator unit to a controlled given value by varying an equivalent input impedance of the power management unit (i.e. the instrumentation block assists the power management unit in the control of the given parameter).

Thus, the proposed self-powered system has the ability to extract energy from the energy generator unit and to perform a measurement simultaneously. Furthermore, the energy extraction from the energy generator unit is performed with maximum efficiency criteria.

In an embodiment, the cited given parameter set by the equivalent input impedance of the power management unit is the polarization voltage of the energy generator unit.

In a particular embodiment, the energy generator unit is a fuel cell.

Thus, the proposed self-powered system can be used for point-of-care (POC) devices, where tracking and amperometric measurement take place at once, in a controlled way, compared to the known prior art solutions. Nonetheless, the system can be also used to control electric batteries, among other applications.

In an embodiment, the instrumentation block comprises a current measurement module electrically connected to the energy generator unit to provide a differential potential V_{S} proportional to the electrical current I_{FC}, and an instrumentation amplifier. The instrumentation amplifier is connected to the current measurement module via a first input and to the energy generator unit via a second input, so that the instrumentation amplifier amplifies the differential potential V_{S} and provides a voltage signal V_{SENSE} proportional to the measured electrical current. The current measurement module particularly comprises a hall sensor or a shunt resistor; however other architectures/elements allowing the measurement of the electrical current can be equally used.

The fuel cell can be a glucose, an ethanol, a lactate or a methanol fuel cell, among others.

In an embodiment, the power management unit comprises a DC-DC converter. In this case, the equivalent input impedance may be set by either varying the duty cycle of the DC-DC converter or alternatively by techniques based on the modulation of the frequency of the DC-DC converter (e.g. a Pulse Frequency Modulation (PFM), a Pulse Width Modulation (PWM), etc.), among others.

In an embodiment, the power management unit also has a maximum power point tracking (MPPT) component that adapts its equivalent input impedance to set an electrical voltage to the voltage reference V_{REF}. For example, this adaptation can be performed by controlling the duty cycle of the power management unit.

In yet another embodiment, the instrumentation block, power management unit and feedback element are integrated in a silicon chip.

Embodiments of the present invention also provide a method for power extraction and measurement of energy-generator units, comprising providing an energy generator unit that delivers an electrical current I_{FC} and a voltage V_{FC}; electrically connecting an instrumentation block to the energy generator unit, and measuring the electrical current I_{FC} delivered by the energy generator unit; electrically connecting a power management unit to the energy generator unit via a first input to collect the electrical current I_{FC}, extracting an electrical power provided by the energy generator unit. According to the invention a feedback element is connected to the power management unit via a second input, the feedback element being further connected to a voltage reference V_{REF}, to the voltage V_{FC} provided by the energy generator unit and to an input of the instrumentation block; and simultaneously to the power extraction, setting, using the power management unit and the instrumentation block, a given parameter of the energy generator unit to a controlled given value by varying an equivalent input impedance of the power management unit.

Embodiments of the present invention also provide the use of the self-powered system for a point-of care device.

The details of one or more embodiments of the disclosure are set forth in the accompanying drawings and the description below. Other features, objects, and advantages will be apparent from the description and drawings, and from the claims.

### BRIEF DESCRIPTION OF DRAWINGS

FIG. 1A and FIG. 1B schematically illustrate common potentiostat architectures used for fuel cell characterization according to the prior art.

FIG. 2 is a block diagram of a self-powered system, according to an embodiment of the present invention.

FIG. 3 is a block diagram of the closed-loop controller structure of the self-powered system of FIG. 2.

FIG. 4 is a schematic of a prototype implemented to show the performance of the proposed self-powered system.

FIG. 5 is a flow chart illustrating a method for power extraction and measurement of energy-generator units, according to an embodiment of the present invention.

FIG. 6 illustrates the measurement concentration and efficiency of a methanol fuel cell, according to an embodiment of the present invention.

FIG. 7 is a block diagram of a self-powered system, according to an embodiment of the present invention.

FIG. 8 illustrates the voltage-current characteristic of the energy generator unit of FIG. 7 for different temperature gradients.

FIG. 9 illustrates the gradient temperature to current transfer function of the energy generator unit of FIG. 7 for a polarization voltage of 0.15 V.

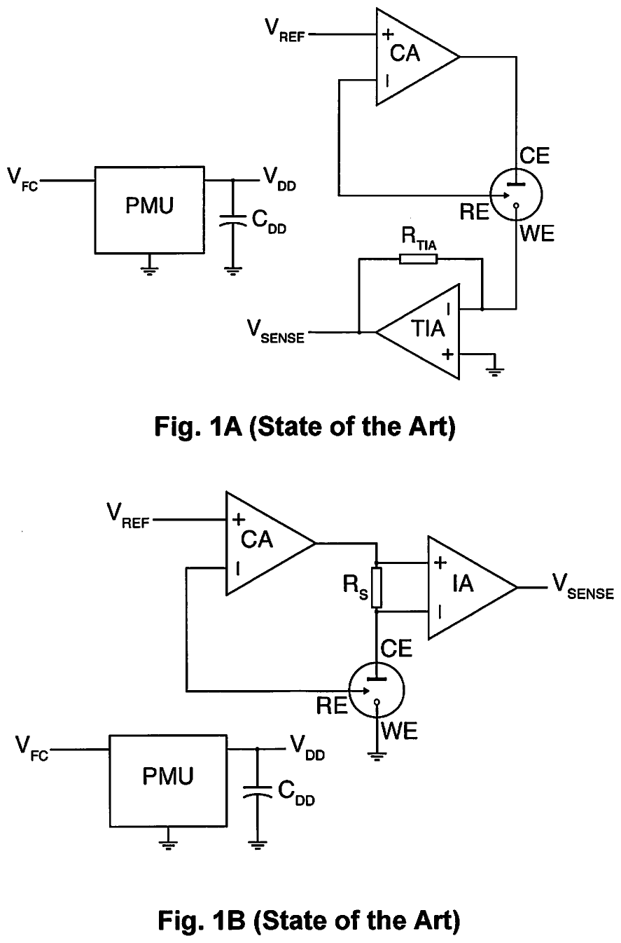

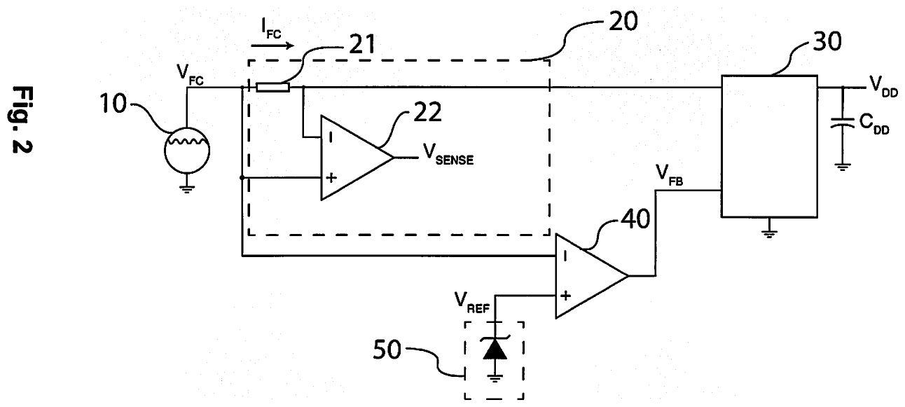

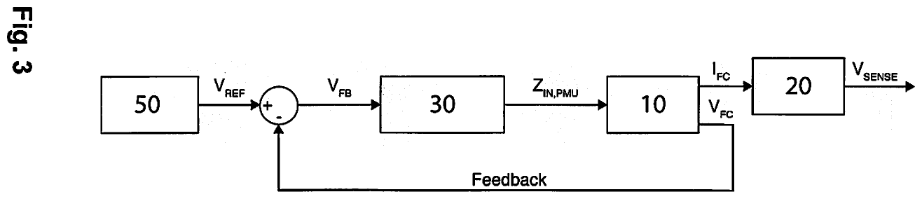

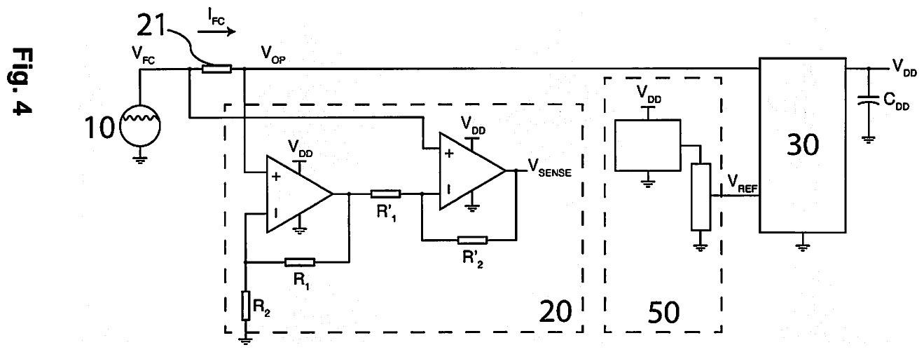

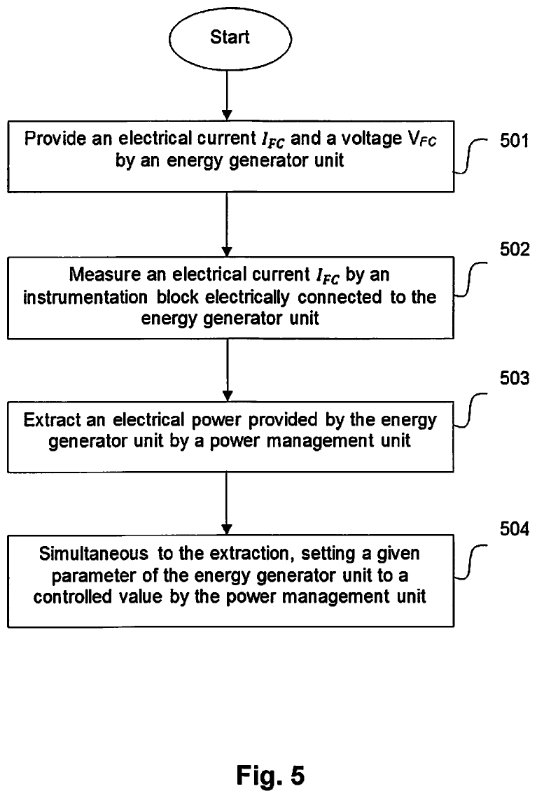

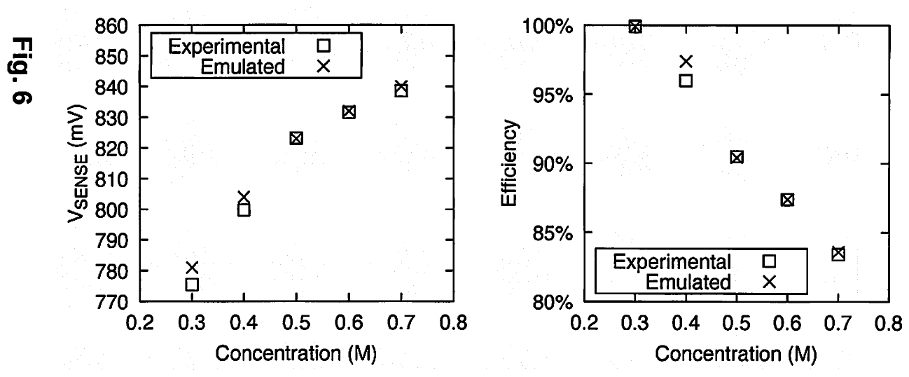

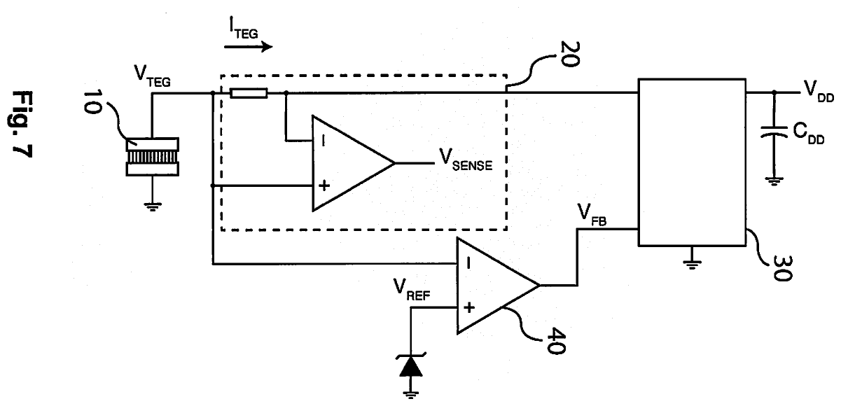

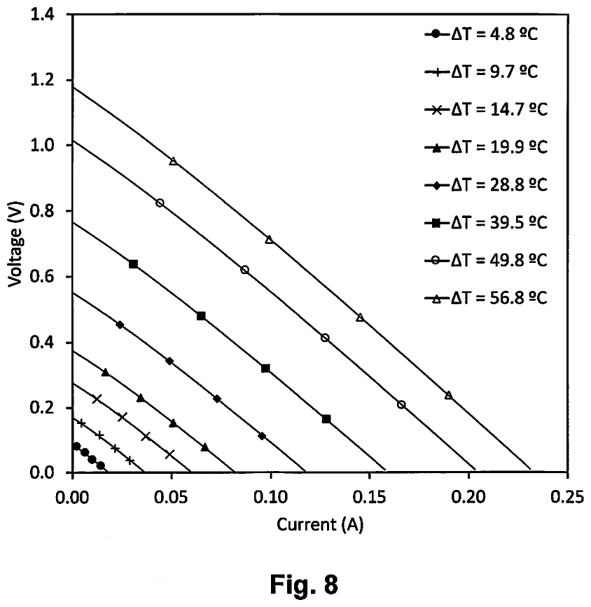

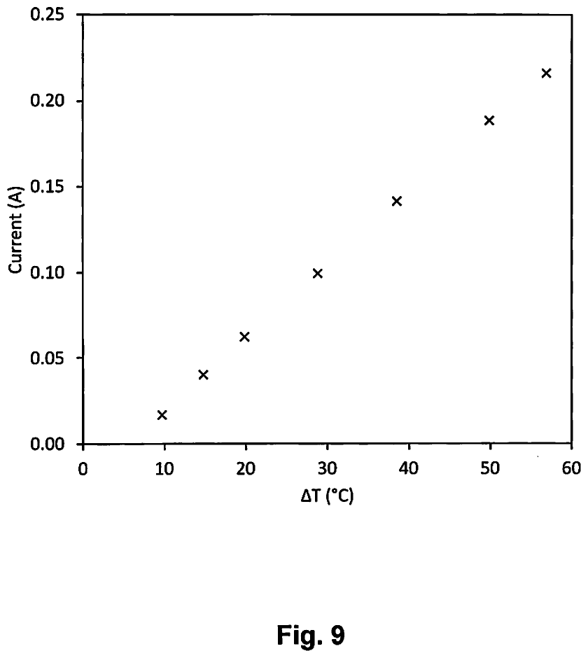

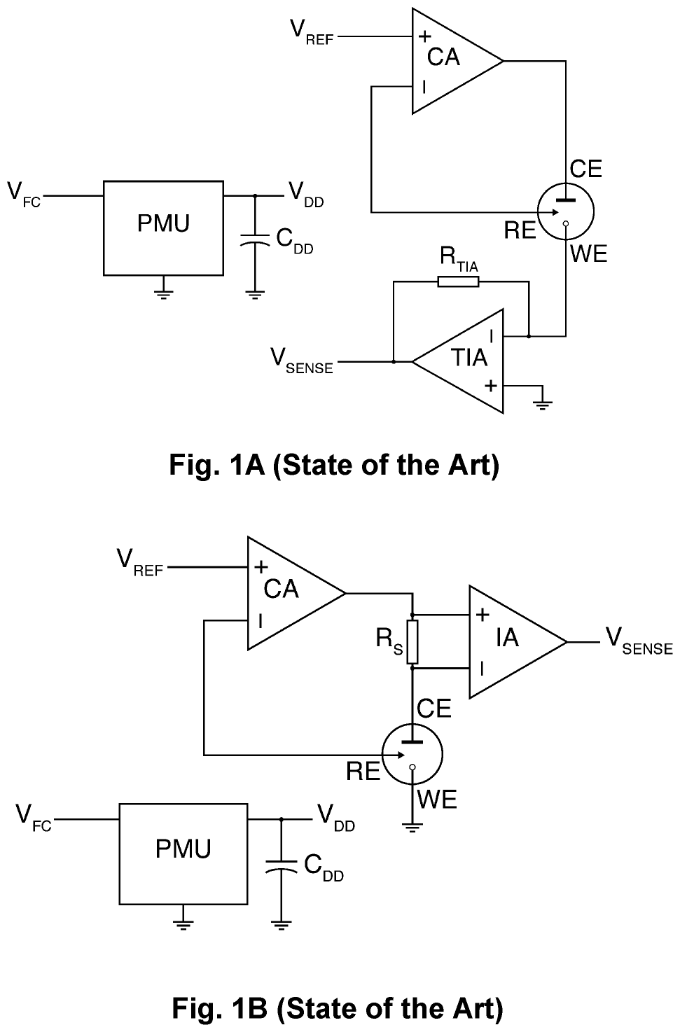

### DESCRIPTION OF EMBODIMENTS

Provided herein are a self-powered system for energy-generator units diagnostic with sensitive-output-characteristics, and a related method for power extraction and concentration measurement of energy-generator units.

FIG. 2 illustrates a self-powered system in accordance with an embodiment of the present invention. The system of FIG. 2 includes an energy generator unit 10 that delivers/provides an electrical current I_{FC} and a voltage V_{FC}, an instrumentation block electrically connected to the energy generator unit 10 to measure the electrical current I_{FC}, a power management unit 30, or PMU from now on, and a feedback element 40, in this particular case implemented as a feedback amplifier.

The PMU 30 is electrically connected to the energy generator unit 10 via a first input and to the feedback element 40 via a second input. The feedback element 40 is electrically connected to a voltage reference V_{REF} provided by element 50, in this particular embodiment a Zener diode, to an input of the instrumentation block 20 and to the voltage V_{FC} provided by the energy generator unit 10.

In the proposed self-powered system, the PMU 30 is the responsible of setting a parameter of the energy generator unit 10 to a controlled given value and the instrumentation block 20 is the responsible of controlling (or assists in the control of) the parameter. The PMU 30 varies its equivalent input impedance in order to lead the parameter to the desired value.

In an embodiment, the equivalent input impedance is set by varying the duty cycle of a DC-DC converter (not shown) of the PMU 30. The duty cycle acts as a control signal setting the input impedance of the PMU 30 of a closed-loop controller system formed by the energy generator unit 10, the PMU 30, the feedback element 40 and the voltage reference V_{REF}. Block diagram of the closed-loop controller system is shown in FIG. 3.

Moreover, the PMU 30 can also include a maximum power point tracking (MPPT) component that adapts the equivalent input impedance to set the electrical voltage of the PMU 30 to the voltage reference V_{REF}.

The criteria to select the voltage level of the voltage reference V_{REF} is application-dependent and a trade-off between the energy generator unit 10 performance as a sensor and as a power source must be considered.

In a particular embodiment, the energy generator unit 10 is a fuel cell such as a glucose, ethanol, lactate or methanol fuel cell. It should be noted that other fuel cells can be also used. In the specific case of using a fuel cell, the PMU 30 varies its equivalent input impedance in order to lead the polarization voltage of the fuel cell to the desired level. Furthermore, for a fuel cell with a better performance as a power source than as a sensor, the polarization voltage will be set closer to V_{SENSOR} (i.e. the polarization voltage) in order to maximize the specifications related to the measurement (sensitivity, repeatability or linearity, among others) in detriment of lower power extraction from the fuel cell. On the other hand, when better performance as a sensor than as a power source is required, the polarization voltage will be set closer to V_{P}_{_{MAX}} in order to maximize the power extracted from the fuel cell.

The instrumentation block 20 can comprise a current measurement module 21 and an instrumentation amplifier 22. The current measurement module 21 is placed in series in the current path between the energy generator unit 10 and the PMU 30. Multiple circuits, sensors and techniques can be used to measure the electrical current I_{FC} (from current measurements modules based in a Hall effect sensor, when high current levels are measured (preferably mA to several A), to current measurement modules based in a shunt, when ultra-low current levels are measured, (preferably from pA to μA), among other solutions to extract a current measurement such as current mirrors, transformers, etc. Again, the measurement technique must be selected as a function of a trade-off between the electrical current levels to be measured and the power available from the energy generator unit 10.

The proposed system provides two major benefits in front of other implementations: 1) the measurement is performed simultaneously with the power extraction, and 2) the energy is extracted with maximum efficiency from the energy generator unit point of view. Common chronoamperometries can take up to several minutes. During these periods, in the common approach of timemultiplexing, PMU 30 remains disconnected and no power is extracted from the energy generator unit 10. This is translated to a previous longer power-extraction times to extract enough energy to perform the measurement, or, directly, to the infeasibility of the measurement. In both cases, not all power generated by the energy generator unit 10 is extracted due to the PMU 30 disconnection during measurement periods. The first benefit solves this by extracting power and measuring simultaneously. The second benefit is achieved when the cited parameter of the energy generator unit 10 is set to a maximum value. Thus, maximum power available from the energy generator unit 10 is achieved allowing longer operation times and/or the possibility of adding more complex (and then with higher power consumption) electronics that allows a better measurement performance or added functionalities (wireless transmission or graphic user interface, among others). In this case, a power extraction level is achieved with the only limitation coming from the energy generator unit 10 performance itself.

A prototype using current available Commercial Off-The-Shelf (COTS) discrete components has been implemented to show the performance of the proposed self-powered system. The ubiquitous characteristic of the proposed system has been validated with different state-of-the-art fuel cells. A detail explanation is described as follows.

State-of-the-art of fuel cells present ranges of the volume from few μL to L. Among some of them, in the case of enzymatic fuel cells, volumes are in the range of μL to mL. Some cases were emulated using a Source Meter Unit (SMU). The SMU permits to emulate real polarization curves extracted from literature. Ethanol and lactate fuel cells were emulated. The fuel cells were also validated with a non-emulated methanol-based fuel cell. A commercial Direct Methanol Fuel Cell (DMFC) was chosen. The DFMC can operate with methanol solutions with concentrations up to 1 M.

The system has been implemented on a double-sided Printed Circuit Board (PCB). FIG. 4 shows a schematic thereof. As a PMU 30, a BQ25504 boost converter was used. In terms of the energy generator unit nature and configuration, input voltage can vary from low voltage levels of few μV to hundreds mV. The BQ25504 provides a regulated output voltage, with the MPPT enabled, from 1.8V up to 3.6V from a lower input voltage. Below 1.8V, the MPPT functionality remains disabled. The regulated output voltage is indicated as V_{DD} and is used to power the front-end and back-end modules, and the user interface. The converter also provides a Power Good (PGOOD) signal that is configured to go high when V_{DD} reaches a voltage level of 3.0V and to go low when it decreases under 2.5V.

The MPPT functionality is used to control the input voltage of the PMU 30 in node V_{OP}. It adapts its equivalent input impedance to set the input voltage equal to the reference voltage V_{REF}. The reference voltage V_{REF} is set, in this case, provided through a high impedance voltage divider 50, to the voltage level where maximum power is extracted from the fuel cell to be used. These optimal voltage levels are 500 mV 225 mV and 200 mV for the fuel cells based in ethanol, lactate and methanol, respectively.

It should be observed that this BQ25504-based implementation slightly differs from the block diagram of FIG. 2. While the purposed solution controls the voltage level at the node indicated as V_{FC}, the BQ25504 has a non-accessible integrated control amplifier that controls the voltage level at the node V_{OP} in FIG. 4. Even so, in a full-custom integrated approximation, voltage level at the node V_{FC} should be controlled by the feedback element 40.

The electrical current delivered/provided by the fuel cell was measured through a shunt resistor and an instrumentation amplifier 22 that provides a signal, indicated as V_{SENSE}, proportional to the measured current. The instrumentation amplifier in this case consisted of a dual operational amplifier. The shunt resistor and instrumentation amplifier 22 gain values were set to 15 and 28.8 VV⁻¹, 15 and 22.3 VV⁻¹, and 0.1 and 77.9 VV⁻¹ for the fuel cells based in ethanol, lactate and methanol, respectively.

For illustration purposes, a back-end module based in a microcontroller module and a user interface based in a LCD display were implemented for the case of a fuel cell based in methanol.

Electrochemical experiments for methanol fuel cell characterization were carried out with the SMU and validated with non-emulated DMFC. Electrochemical experiments were carried out for a concentration range from 0.3 to 0.7 M with concentration steps of 0.1 M. For a given concentration, OCV was stable and above the expected OCV of 500 mV, polarization curve was extracted between OCV and 0 V at a scan rate of 1 mV s⁻¹.

The system has been fully characterized in terms of power consumption, transfer function, power efficiency from fuel cell point of view and start-up time. The power consumption was measured with the SMU. The transfer functions for the different fuel cells, emulated and implemented, have been extracted by measuring V_{SENSE} for different fuel concentrations once steady-state operation is reached. The analog signal was captured with an oscilloscope. The power efficiency was measured by monitoring the current, using SMU facilities. Start-up characterization was performed by capturing V_{FC}, V_{DD}, V_{REF}, V_{SENSE} and V_{PGOOD} during the system's start-up transient with two oscilloscopes along with the SMU in common triggered configuration.

The solution exhibited a minimum efficiency and maximum start-up time for the ethanol, lactate and methanol-based fuel cells of 95% and 9 s, 90% and 12 s, and 85% and under 1 s, respectively.

The present invention also relates to a method for simultaneous power extraction and concentration measurement of energy-generator units.

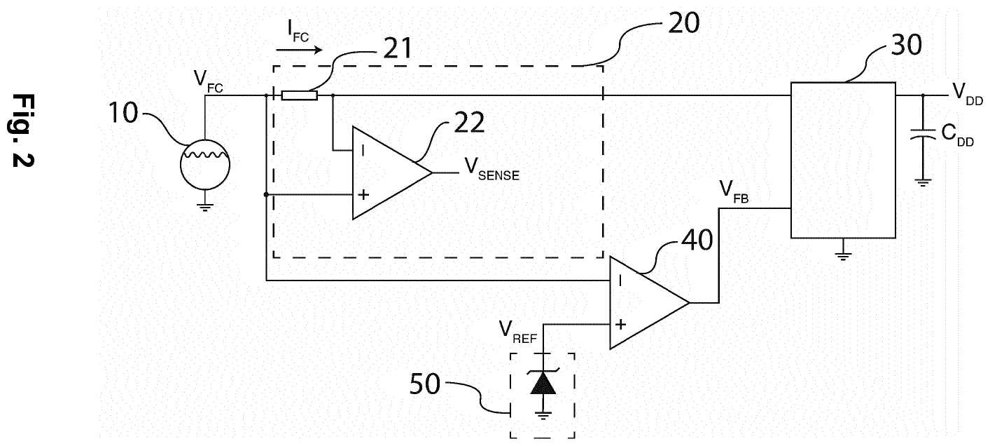

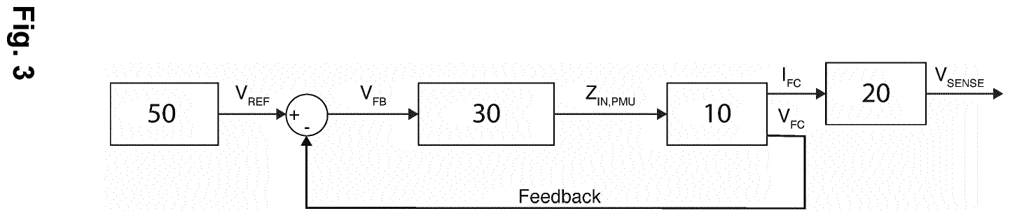

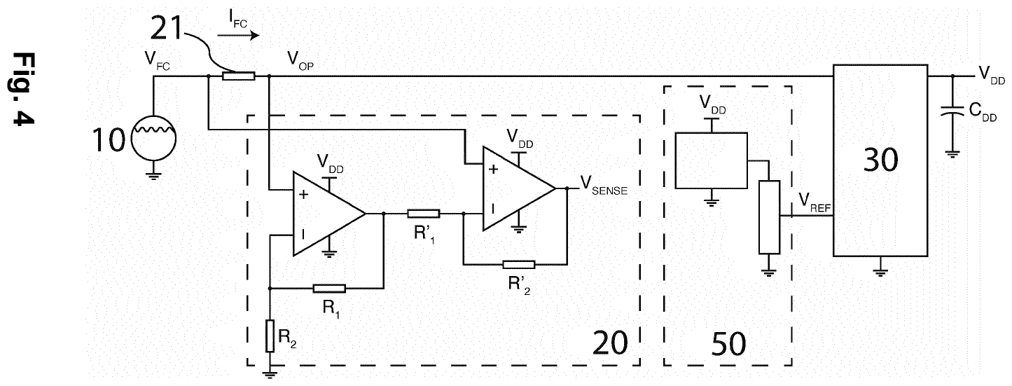

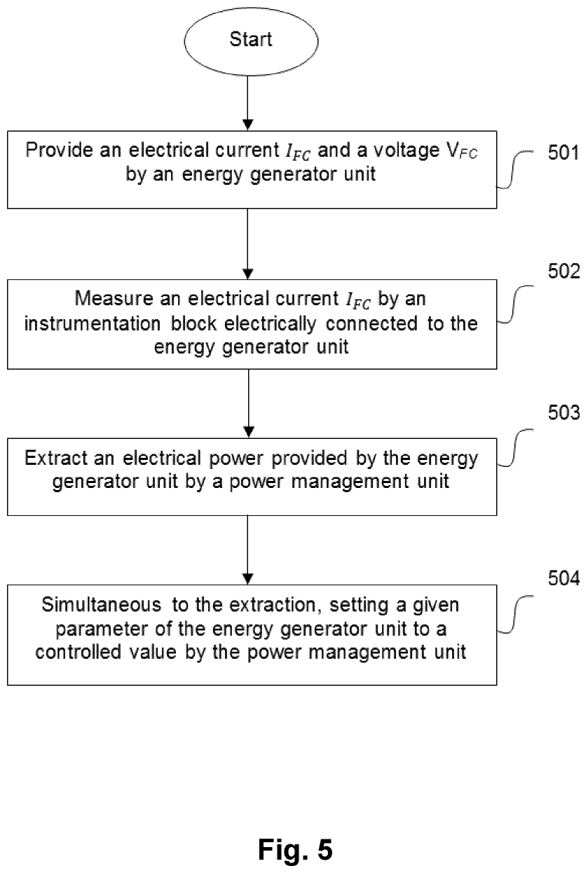

FIG. 5 shows an embodiment of the method. The method starts by providing an electrical current I_{FC} and a voltage V_{FC} by an energy generator unit (step 501). When an instrumentation block is electrically connected to the energy generator unit, the instrumentation block measures the electrical current I_{FC} (step 502). The PMU then extracts an electrical power provided by the energy generator unit (step 503) and simultaneously sets a given parameter of the energy generator unit to a controlled value (step 504) by varying its equivalent input impedance. The instrumentation block assists in the control of the parameter.

In a specific embodiment, the given parameter is the polarization voltage of a fuel cell.

With reference to FIG. 6, therein it is illustrated the measurement concentration and efficiency of a methanol fuel cell, according to a particular embodiment of the present invention. The transfer function has been extracted by measuring V_{SENSE} in terms of the concentration for the emulated and experimental fuel cell. There is a direct relationship between the lecture and the concentration of the sample. In terms of efficiency, the extracted energy is kept very high while the measurement takes place. The small deviation between these data validates the methodology for the emulated fuel cells.

Although specific embodiments have been detailed using a fuel cell as energy generator unit 10, the teaching of the present invention can be applied to other energy generator units such as galvanic cells, electrical energy transducers, thermoelectric generators (TEG), or electrical batteries, among others.

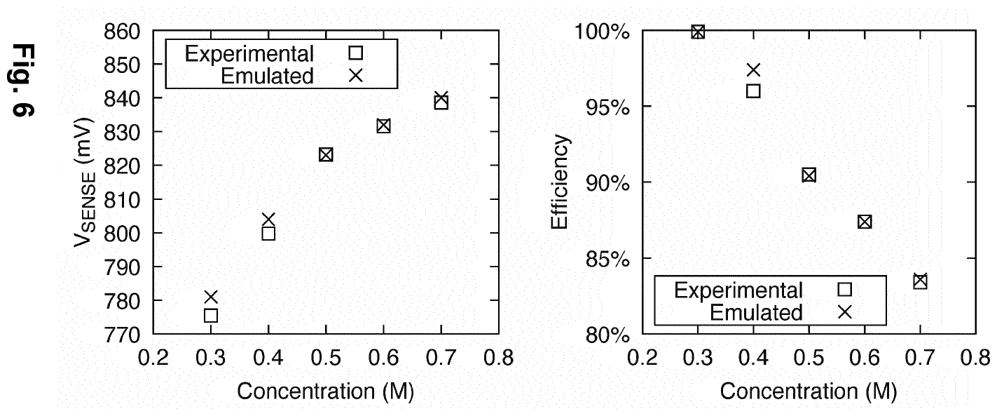

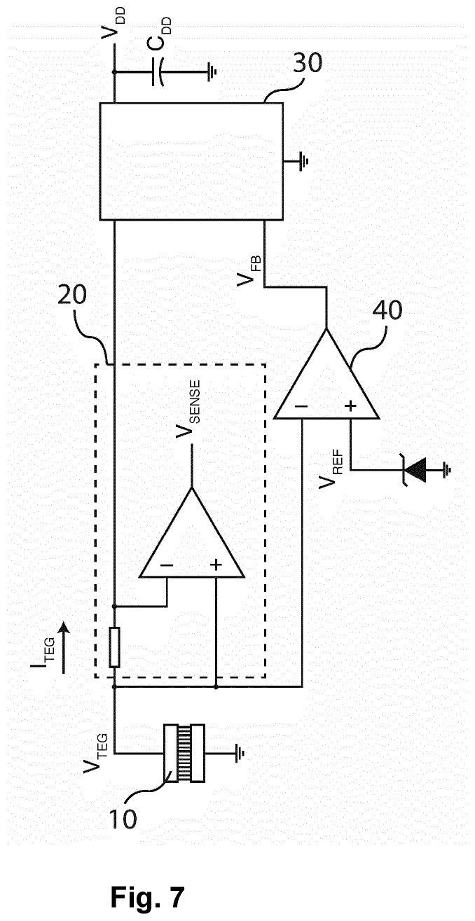

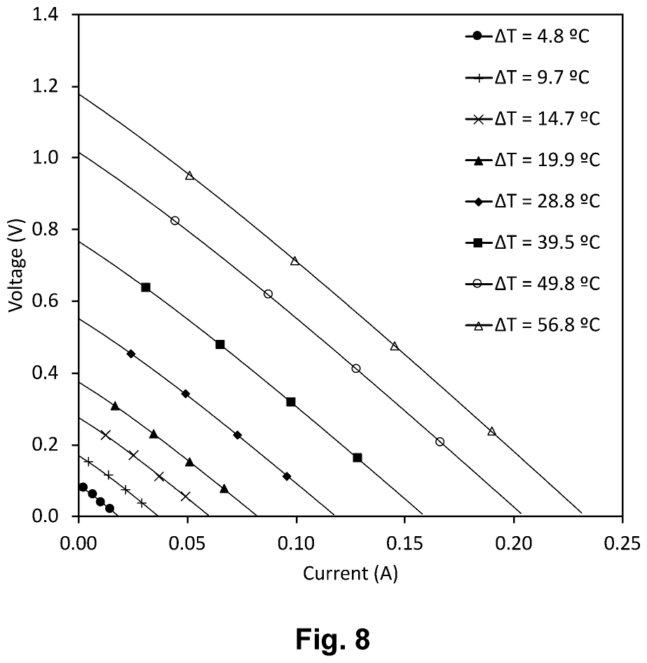

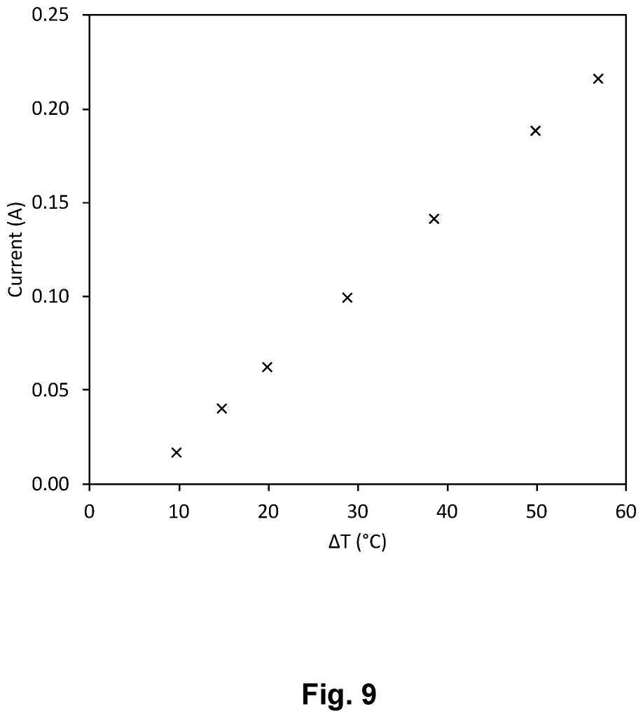

In particular, FIG. 7 illustrates an embodiment of the proposed self-powered system using a TEG as energy generator unit 10. The voltage-current characteristic of a commercial off-the-shelf thermoelectric generator for different temperature gradients is shown in FIG. 8. Varying the equivalent input impedance of the PMU 30, the operating point of the TEG is controlled to a desired state by means of the thermoelectric generator's output voltage. Once fixed, measuring the current outputted by the TEG, a parameter related to the TEG can be measured. In this application-specific case, the temperature gradient across the thermoelectric generator can be monitored, as depicted in FIG. 9.

The foregoing describes embodiments of the present invention and modifications, obvious to those skilled in the art can be made thereto, without departing from the scope of the present invention.

What is claimed is:

1. A self-powered system, comprising:
an energy generator unit configured to provide an electrical current I_{FC} and a voltage V_{FC};
an instrumentation block electrically connected to said energy generator unit and configured to measure said electrical current I_{FC} provided by said energy generator unit;
a power management unit electrically connected to said energy generator unit via a first input to collect said electrical current I_{FC}, and configured to extract an electrical power provided by the energy generator unit;
a feedback element electrically connected to said power management unit via a second input of said power management unit, said feedback element further being electrically connected to a voltage reference V_{REF}, to the voltage V_{FC} provided by said energy generator unit and to an input of said instrumentation block, such that, simultaneously to the extraction of the electrical power by the power management unit, said power management unit, and said instrumentation block are cooperatively configured to set a given parameter of said energy generator unit to a controlled given value by varying an equivalent input impedance of said power management unit,
said energy generation unit, said power management unit, said feedback element and the voltage reference V_{REF} being collectively structured to define a closed loop controller system.

2. The system according to claim 1, wherein said given parameter set by said equivalent input impedance of said power management unit is a polarization voltage of said energy generator unit.

3. The system according to claim 1, wherein said energy generator unit comprises a fuel cell.

4. The system according to claim 1, wherein said instrumentation block comprises a current measurement module electrically connected to said energy generator unit to provide a differential potential V_{S} proportional to said electrical current I_{FC}, and an instrumentation amplifier, said instrumentation amplifier being connected to said current measurement module via a first input and to said energy generator unit via a second input, so that said instrumentation amplifier amplifies the differential potential V_{S} and provides a voltage signal V_{SENSE} proportional to the measured electrical current.

5. The system according to claim 4, wherein said current measurement module comprises a shunt resistor or a hall sensor.

6. The system according to claim 3, wherein said fuel cell is a glucose, ethanol, lactate or methanol fuel cell.

7. The system according to claim 1, wherein the power management unit comprises a DC-DC converter, and wherein said equivalent input impedance is set by varying a duty cycle of said DC-DC converter.

8. The system according to claim 1, wherein the power management unit comprises a DC-DC converter, and wherein said equivalent input impedance is set by a frequency modulation technique of said DC-DC converter.

9. The system according to claim 1, wherein said power management unit further comprises a maximum power point tracking (MPPT) component configured to adapt said equivalent input impedance to set an electrical voltage of said power management unit to said voltage reference V_{REF}.

10. The system according to claim 1, wherein said instrumentation block, said power management unit and said feedback element are integrated in a silicon chip.

11. A method for power extraction and measurement of energy-generator units, comprising:
providing an energy generator unit that delivers an electrical current I_{FC} and a voltage V_{FC};
providing an instrumentation block electrically connected to the energy generator unit, and using the instrumentation block to measure the electrical current I_{FC} delivered by the energy generator unit;
providing a power management unit electrically connected to the energy generator unit via a first input configured to collect the electrical current I_{FC}, using the power management unit to extract an electrical power provided by the energy generator unit;
providing a feedback element electrically connected to the power management unit via a second input of the power management unit, the feedback element being further connected to a voltage reference V_{REF}, to the voltage V_{FC} provided by the energy generator unit and to an input of the instrumentation block; and
simultaneously to the power extraction, using the power management unit and the instrumentation block to set a given parameter of the energy unit to a controlled given value by varying an equivalent input impedance of the power management unit,
the energy generation unit, the power management unit, the feedback element and the voltage reference V_{REF} being collectively structured to define a closed loop controller system.

12. The method according to claim 11, wherein the given parameter is a polarization voltage of the energy generator unit, which is a fuel cell including a glucose, ethanol, lactate or methanol fuel cell.

13. The method according to claim 11, wherein the power management unit comprises a DC-DC converter, and wherein the equivalent input impedance is set by varying a duty cycle of the DC-DC converter or by a frequency modulation technique of the DC-DC converter.

14. The method according to claim 11, further comprising setting an electrical voltage of the power management unit to the voltage reference V_{REF} by a maximum power point tracking (MPPT) component.

15. The system of claim 1, configured as a point-of care device.
